(19) United States
(12) Patent Application Publication
(10) Pub. No.: US 2019/0319080 A1
(43) Pub. Date: Oct. 17, 2019

(54) DISPLAY APPARATUS AND MANUFACTURING METHOD THEREOF

(71) Applicant: Au Optronics Corporation, Hsinchu (TW)

(72) Inventors: Tsung-Ying Ke, Tainan City (TW); Yung-Chih Chen, Taichung City (TW); Keh-Long Hwu, Hsinchu County (TW); Wan-Tsang Wang, Hsinchu (TW); Chun-Hsin Liu, Yunlin County (TW)

(73) Assignee: Au Optronics Corporation, Hsinchu (TW)

(21) Appl. No.: 16/166,172

(22) Filed: Oct. 22, 2018

(30) Foreign Application Priority Data
Apr. 17, 2018 (TW) 107113092

(51) Int. Cl. H01L 27/32; H01L 25/18

(52) U.S. Cl. CPC H01L 27/3253; H01L 27/3276; H01L 27/124; H01L 27/3262; H01L 27/3265; H01L 25/18

(57) ABSTRACT

A display apparatus and a manufacturing method thereof are provided. The display apparatus includes a signal line substrate, pixel circuit substrates, light emitting device layer, first vertical connection structures and second vertical connection structures. The signal line substrate includes signal lines and vertical signal connection structures electrically connected with the signal lines. The pixel circuit substrates are stacked on the signal line substrate, and respectively include a pixel circuit. The light emitting device layer is disposed on the pixel circuit substrates, and includes light emitting devices. The first and second vertical connection structures are disposed in the pixel circuit substrates. The first vertical connection structures are electrically connected between the light emitting devices and the pixel circuits, respectively. The second vertical connection structures are electrically connected between the pixel circuits and the vertical signal connection structures, respectively.

### CROSS-REFERENCE TO RELATED APPLICATION

This application claims the priority benefit of Taiwan application serial no. 107113092, filed on Apr. 17, 2018. The entirety of the above-mentioned patent application is hereby incorporated by reference herein and made a part of this specification.

### BACKGROUND

### Field of the Invention

The invention relates to a display apparatus and more particularly, to a display apparatus having multiple substrates.

### Description of Related Art

Along with the increasingly developed technology industry, display apparatuses, such as mobile phones, tablet computers or eBooks, have been widely applied in daily life in recent years. In addition to the display performance of a display apparatus regarding resolution, contrast and viewing angle, consumers' requirements on appearance of the display apparatus have also been increased. Generally, a border region surrounding a display region is one of the major factors which have negative impacts on the appearance of the display apparatus. Therefore, how to reduce the border width without influencing the display performance of the display apparatus has become an important subject in this field.

### SUMMARY

The invention provides a display apparatus that can achieve an object of a narrow-border or borderless design.

The invention provides a manufacturing method of a display apparatus that can reduce a border width of the display apparatus.

A display apparatus of the invention includes a signal line substrate, a plurality of pixel circuit substrates, a light emitting device layer, a plurality of first vertical connection structures and a plurality of second vertical connection structures. The signal line substrate includes a plurality of signal lines and a plurality of vertical signal connection structures. The vertical signal connection structures are electrically connected with the signal lines respectively. The pixel circuit substrates are stacked on the signal line substrate. Each of the pixel circuit substrates includes a pixel circuit. The light emitting device layer is disposed on the pixel circuit substrates. The light emitting device layer includes a plurality of light emitting devices. The first vertical connection structures are disposed in the pixel circuit substrates. The first vertical connection structures are electrically connected between the light emitting devices and the pixel circuits respectively. The second vertical connection structures are disposed in the pixel circuit substrates. The second vertical connection structures are electrically connected between the pixel circuits and the vertical signal connection structures respectively.

In an embodiment of the invention, each of the pixel circuits may include at least one transistor.

In an embodiment of the invention, at least one of the first vertical connection structures may penetrate at least one of the pixel circuit substrates.

In an embodiment of the invention, at least one of the second vertical connection structures may penetrate at least one of the pixel circuit substrates.

In an embodiment of the invention, a plurality of orthographic projections of the pixel circuits on the signal line substrate may overlap with one another.

In an embodiment of the invention, a plurality of orthographic projections of the light emitting devices and of the pixel circuits on the signal line substrate may overlap with one another.

In an embodiment of the invention, the display apparatus may further include a first anisotropic conductive layer and a plurality of second anisotropic conductive layers. The first anisotropic conductive layer is disposed between the signal line substrate and the pixel circuit substrates, and each of the second anisotropic conductive layers is disposed between two of the pixel circuit substrates.

A manufacturing method of a display apparatus according to the embodiments of the invention includes the following steps. A signal line substrate is formed. The signal line substrate includes a plurality of signal lines and a plurality of vertical signal connection structures electrically connected with a plurality of signal lines respectively. A plurality of pixel circuit substrates are formed. Each of the pixel circuit substrates includes a pixel circuit substrate and a plurality of vertical connection structures. A light emitting device layer is formed on one of the pixel circuit substrates. The light emitting device layer includes a plurality of light emitting devices. The pixel circuit substrates are bonded and stacked with one another on the signal line substrate. The light emitting device layer covers the pixel circuits. The light emitting devices are respectively electrically connected with the pixel circuits via a first set of the vertical connection structures and are respectively electrically connected with the pixel circuits via a second set of the vertical connection structures.

In an embodiment of the invention, before the step of bonding and stacking the pixel circuit substrates with one another on the signal line substrate, the manufacturing method of the display apparatus may further include the following steps. A first anisotropic conductive layer is formed on the signal line substrate. A second anisotropic conductive layer is formed on at least one of the pixel circuit substrates.

In an embodiment of the invention, the signal line substrate may include a transparent substrate and an insulation layer. The insulation layer is formed on the transparent substrate, and the signal lines and the vertical signal connection structures are formed in the insulation layer.

In an embodiment of the invention, after the step of bonding and stacking the pixel circuit substrates with one another on the signal line substrate, the manufacturing method of the display apparatus may further include bonding the signal line substrate onto a transparent substrate.

To sum up, in the embodiments of the invention, by stacking the pixel circuit substrates stacked on the signal line substrate, the pixel circuits can be disposed on different horizontal planes within the same pixel region. In comparison with the pixel circuits which are formed on the same horizontal plane within the same pixel region, a layout area of each pixel circuit may be less restricted in the embodiments of the invention. In this way, a process margin can be increased. In addition, an area of the pixel region can also be reduced, thereby increasing a resolution of the display apparatus. On the other hand, in comparison with cases where some of the signal lines are disposed in the periphery (a border region) of the pixel region, all the signal lines can be disposed under the pixel circuits in the embodiments of the invention. In other words, all the signal lines can be formed within the range of the pixel region in the embodiments of the invention. In this way, the display apparatus of the embodiments of the invention can achieve the object of a narrow-border or borderless design.

To make the above features and advantages of the invention more comprehensible, embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flowchart illustrating a manufacturing method of a display apparatus according to some embodiments of the invention.

FIG. 2A to FIG. 2H are schematic cross-sectional views illustrating various intermediate stages in the manufacturing method of the display apparatus according to some embodiments of the invention.

FIG. 3 is a schematic three-dimensional (3D) exploded view illustrating a display apparatus according to some embodiments of the invention.

FIG. 4 is a schematic cross-sectional view illustrating a display apparatus according to some embodiments of the invention.

### DESCRIPTION OF EMBODIMENTS

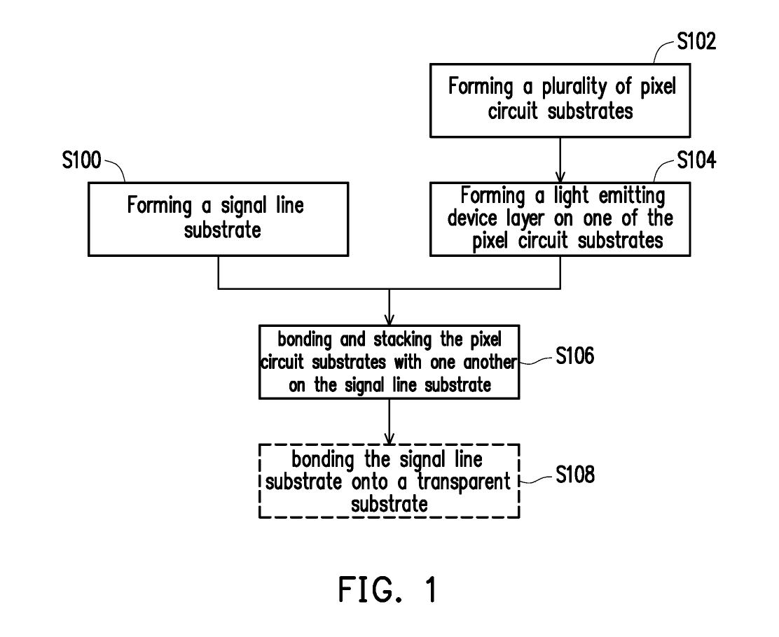

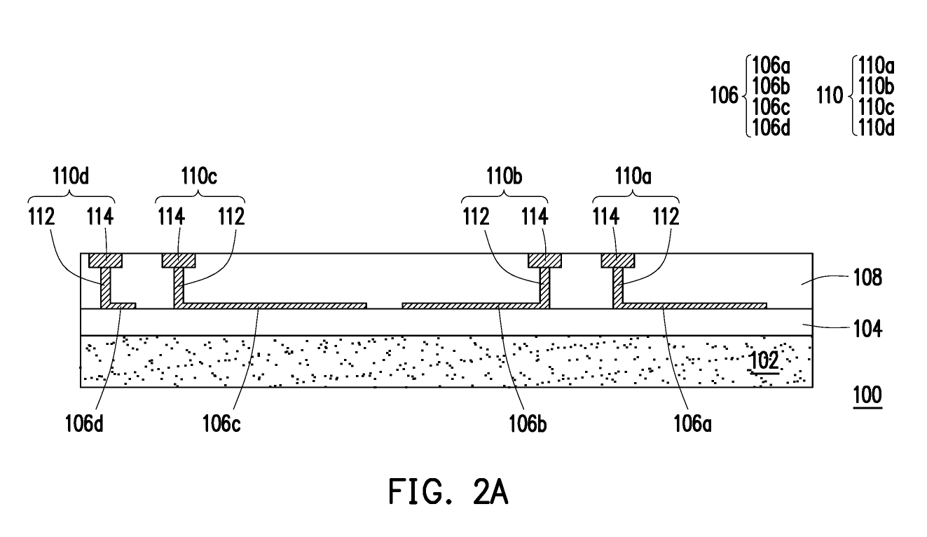

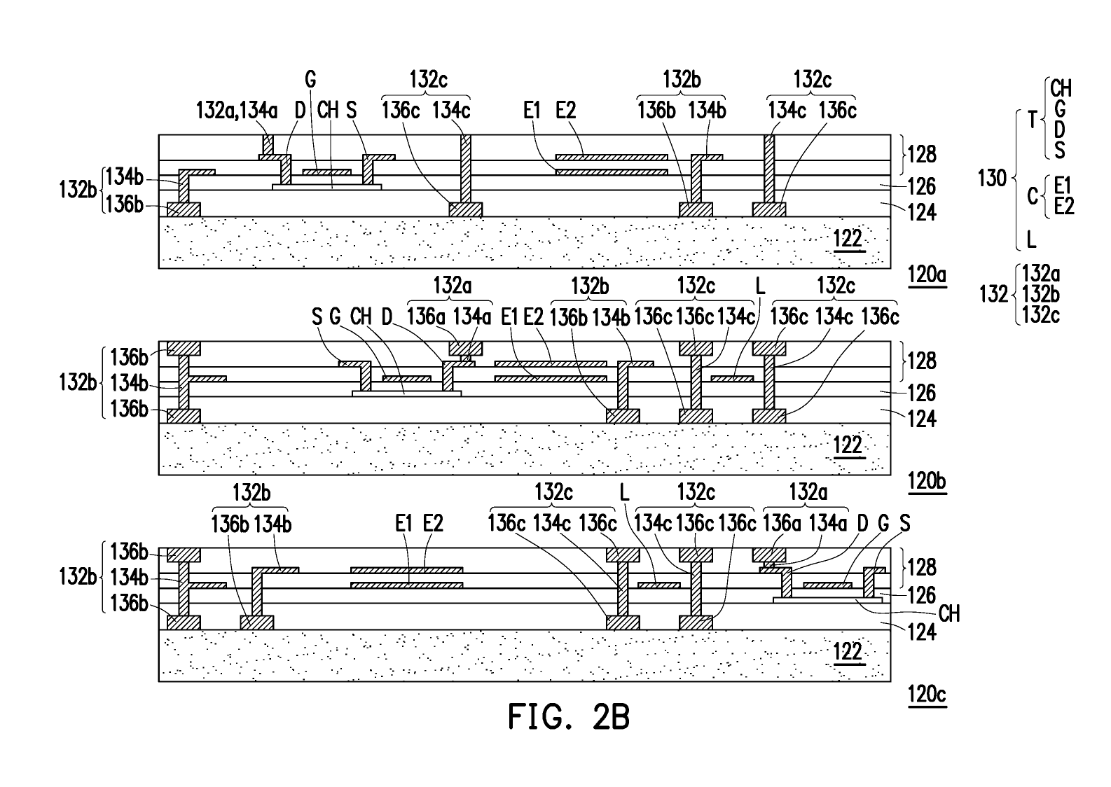

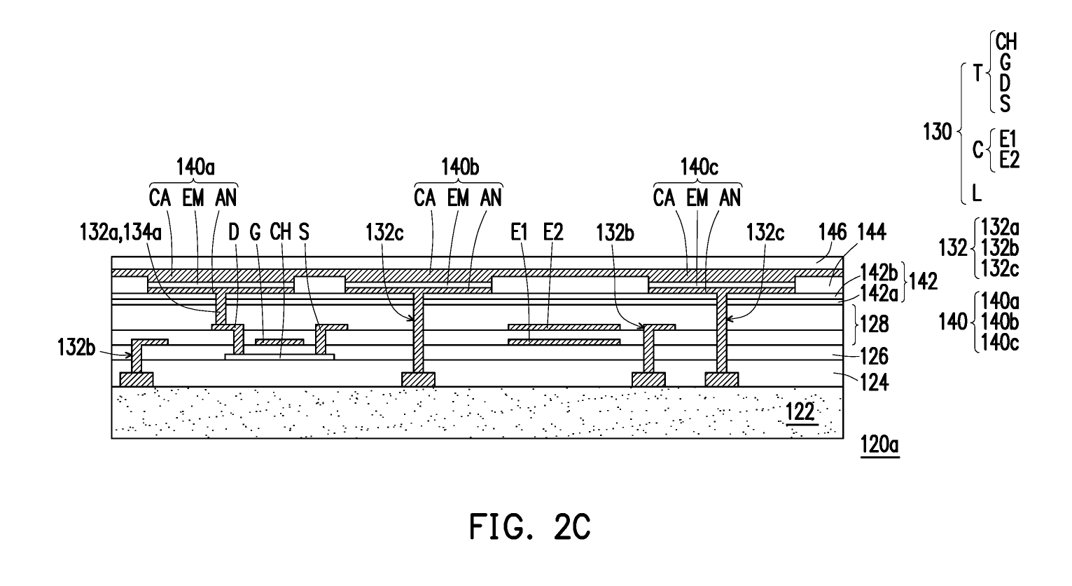

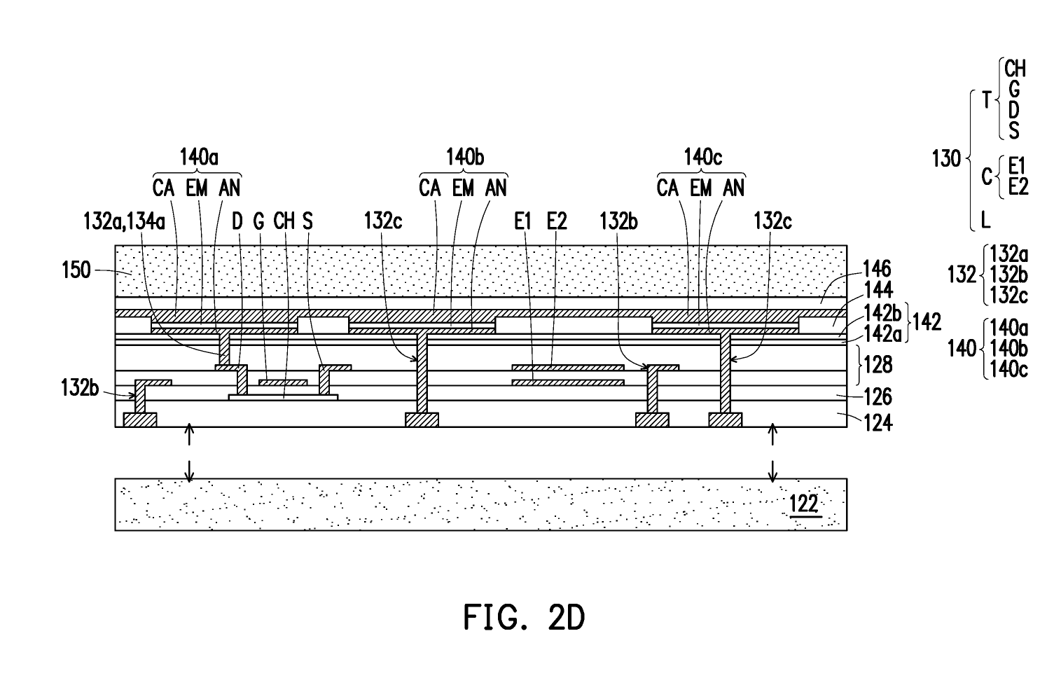

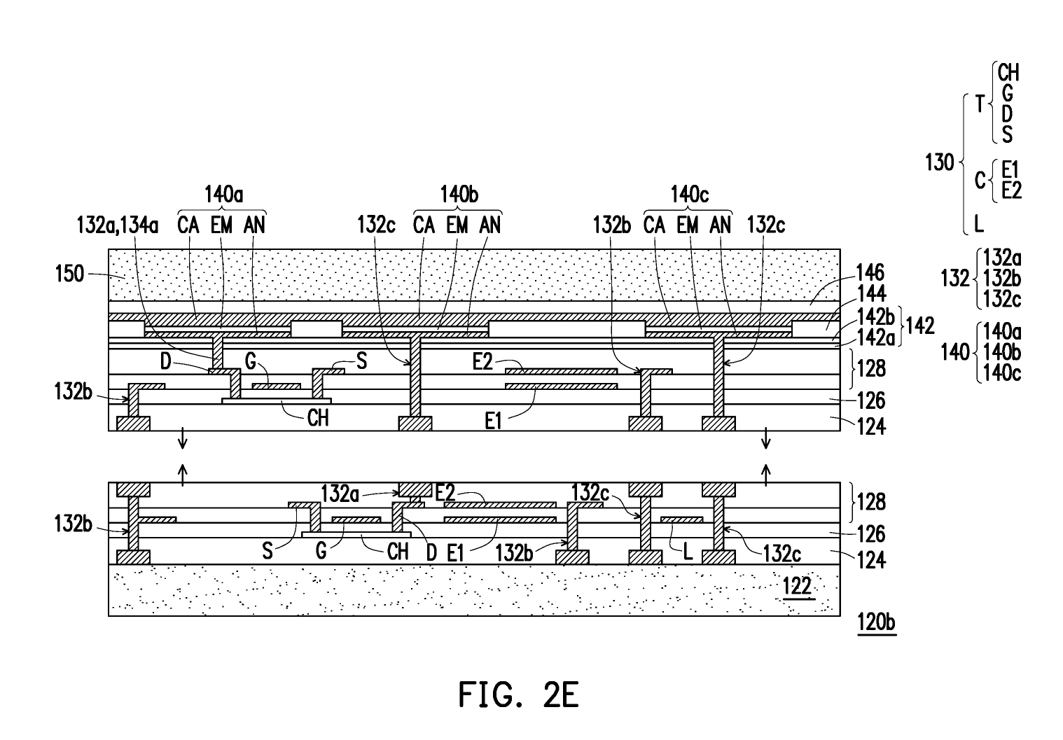

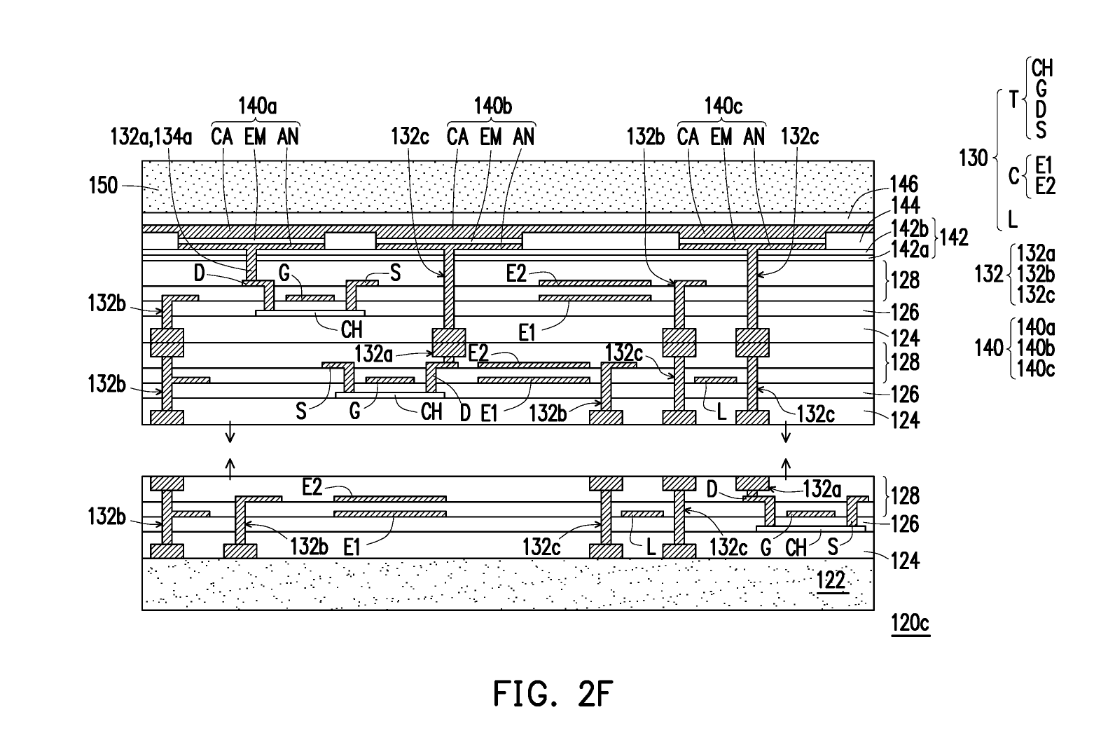

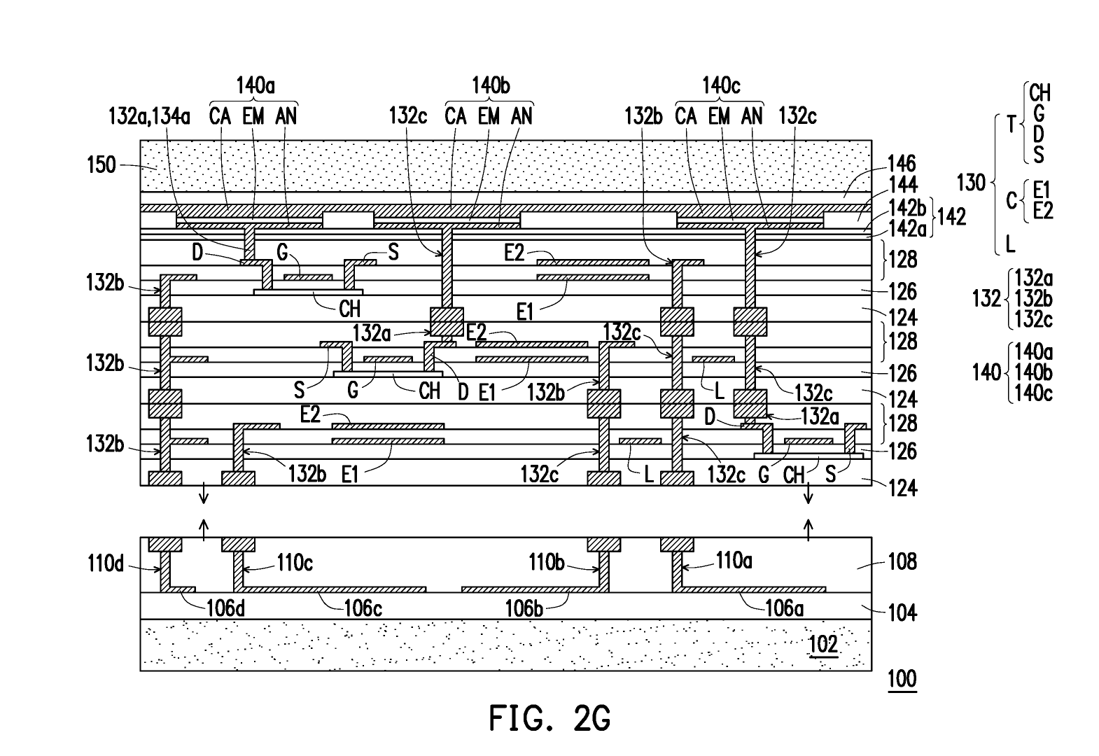

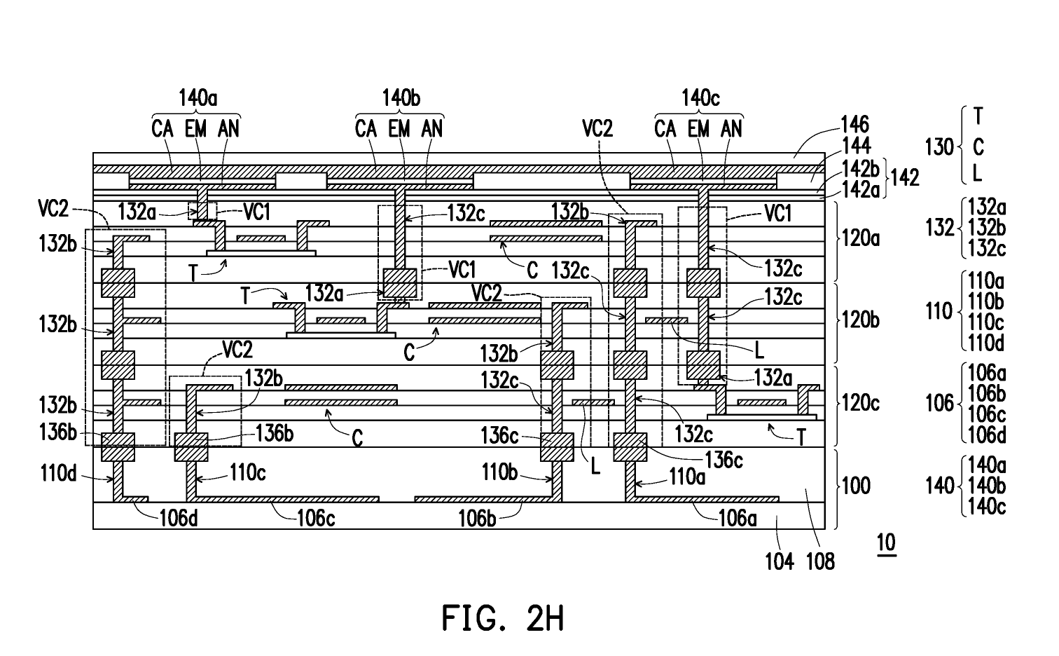

FIG. 1 is a flowchart illustrating a manufacturing method of a display apparatus 10 according to some embodiments of the invention. FIG. 2A to FIG. 2H are schematic cross-sectional views illustrating various intermediate stages in the manufacturing method of the display apparatus 10 according to some embodiments of the invention. A manufacturing method of the display apparatus 10 according to the embodiments of the invention includes the following steps.

Referring to FIG. 1 and FIG. 2A, step S100 is performed, where a signal line substrate 100 is formed. In some embodiments, a method of forming the signal line substrate 100 may include forming a substrate 104 on a first carrier 102. The substrate 104 may be made of silicon oxide, silicon nitride, a polymer material or a combination thereof. For example, the polymer material may include polyimide (PI), polystyrene (PS), polytetrafluoroethylene (PTFE), a phenol-formaldehyde resin, an epoxy resin, an acrylic resin or a combination thereof. In some embodiments, a thickness of the substrate 104 may be 10 nm to 2 μm. In some other embodiments, the thickness of the substrate 104 may also be 0.1 μm to 40 μm. Additionally, in some embodiments, an adhesive layer (not shown) may be further formed on the first carrier 102, such that the adhesive layer may be located between the first carrier 102 and the substrate 104. The adhesive layer may be, for example, a light-to-heat conversion (LTHC) layer, an ultraviolet (UV) glue, a release layer or a combination thereof.

The method of forming the signal line substrate 100 may further include forming a plurality of signal lines 106 on the substrate 104. For example, the signal lines 106 may include a signal line 106a, a signal line 106b, a signal line 106e and a signal line 106d. For example, each of the signal lines 106 may be made of copper, aluminum, silver, titanium, molybdenum or a combination thereof. Each of the signal lines 106 may be employed as a scan line, a data line, a working electrode or a reference electrode. Thereafter, an insulation layer 108 may be formed on the signal lines 106, and a plurality of vertical signal connection structures 110 are formed in the insulation layer 108. The insulation layer 108 may be made of silicon oxide, silicon nitride, a polymer material or a combination thereof. For example, the polymer material may include polyimide (PI), polystyrene (PS), polytetrafluoroethylene (PTFE), a phenol-formaldehyde resin, an epoxy resin, an acrylic resin or a combination thereof. In some embodiments, the insulation layer 108 may be a single-layer structure. In other embodiments, the insulation layer 108 may be a multi-layer structure. In addition, the insulation layer 108 and the substrate 104 may be composed of the same material or difference materials. In some embodiments, the vertical signal connection structures 110 may include a vertical signal connection structure 110a, a vertical signal connection structure 110b, a vertical signal connection structure 110c and a vertical signal connection structure 110d. The vertical signal connection structures 110a, 110b, 110c and 110d may be electrically connected with the signal lines 106a, 106b, 106c and 106d, respectively. In some embodiments, each of the vertical signal connection structures 110 may include a conductive via 112 and a pad 114. The conductive via 112 is electrically connected between the signal line 106 and the pad 114. The conductive vias 112 and the pads 114 may be respectively made of copper, aluminum, silver, titanium, molybdenum or a combination thereof. In some embodiments, the conductive vias 112 and the pads 114 may be formed in the same process step, such that the conductive vias 112 and the pads 114 are composed of the same material. In other embodiments, the conductive vias 112 and the pads 114 may be formed in different process steps, such that the material of the conductive vias 112 may be different from the material of the pads 114. In some embodiments, top surfaces of the pads 114 may be substantially coplanar with a top surface of the insulation layer 108. In other embodiments, the pads 114 may be formed on the top surface of the insulation layer 108. In other words, the conductive vias 112 may extend to the top surface of the insulation layer 108 and electrically connected with the pads 114 on the insulation layer 108.

Referring to FIG. 2B, step S102 is performed, where a plurality of pixel circuit substrates are formed. In some embodiments, three pixel circuit substrates may be formed in step S102, which include a pixel circuit substrate 120a, a pixel circuit substrate 120b and a pixel circuit substrate 120c. In other embodiments, four or more pixel circuit substrates may be formed in step S102, and the number of the pixel circuit substrates is not limited in the invention. Taking the pixel circuit substrate 120a as an example, a method of forming each of the pixel circuit substrates may include sequentially forming a substrate 124, a dielectric layer 126 and an insulation layer 128 on a first carrier 122. Being similar to the first carrier 102 illustrated in FIG. 2A, the first carrier 122 may be a glass carrier. Being similar to the substrate 104 illustrated in FIG. 2A, the substrate 124 may be made of silicon oxide, silicon nitride, a polymer material or a combination thereof. In some embodiments, a thickness of the substrate 124 may be 10 nm to 2 μm. In some other embodiments, the thickness of the substrate 124 may also be 0.1 μm to 40 μm. In some embodiments, the dielectric layer 126 may be made of silicon oxide, silicon nitride or a material with high dielectric constant (where the dielectric constant is, for example, greater than 3). The insulation layer 128 may be made of silicon oxide, silicon nitride, a polymer material or a combination thereof. In some embodiments, the insulation layer 128 may be a multi-layer structure. In other embodiments, the insulation layer 128 may also be a single-layer structure. Additionally, in some embodiments, an adhesive layer (not shown) may be further formed on the first carrier 122 before the substrate 124 is formed. The adhesive layer may be, for example, a LTHC layer, a UV glue, a release layer or a combination thereof.

A method of forming each of the pixel circuit substrates may include forming a pixel circuit 130 on the substrate 124. Each of the pixel circuits 130 may include at least one transistor T. In some embodiments, the number of the transistors T in each of the pixel circuits 130 may range from 1 to 7, but the invention is not limited thereto. The pixel circuit 130 may be formed in the dielectric layer 126 and the insulation layer 128. In some embodiments, the transistor T may include a channel layer CH, a gate electrode G, a drain electrode D and a source electrode S. In some embodiments, the transistor T may be formed as a top-gate type structure. The channel layer CH may be formed on the substrate 124, and the dielectric layer 126 may cover the channel layer CH. The gate electrode G is formed on the dielectric layer 126. Orthographic projections of the gate electrode G and the channel layer CH on the substrate 124 may overlap with each other. The dielectric layer 126 between the gate electrode G and the channel layer CH may be employed as a gate dielectric layer of the transistor T. The insulation layer 128 is formed on the dielectric layer 126, and covers the gate electrode G. The drain electrode D and the source electrode S are located in the insulation layer 128, and extend into the dielectric layer 126 to be electrically connected with the channel layer CH respectively. The drain electrode D and the source electrode S may be located on opposite sides of the gate electrode G. In other embodiments, the transistor T may also be formed as a bottom-gate type structure. Those with ordinary skills in the art may adjust the arrangement of the channel layer CH, the gate electrode G, the drain electrode D and the source electrode S in the transistor T based on a design requirement, the invention is not limited thereto. The channel layer CH may be made of amorphous silicon, low temperature poly silicon (LTPS), transition metal oxide or a combination thereof. The gate electrode G, the drain electrode D and the source electrode S may be respectively made of a metal material, any other conductive material or a stack structure consisting of the metal material and the afore-mentioned any other conductive material. The metal material may include aluminum, copper, molybdenum, titanium and so on, and the afore-mentioned conductive material may include a metal alloy, metal nitride, metal oxide, metal oxynitride, or another suitable material.

In some embodiments, each of the pixel circuits 130 may further include a capacitor C. The capacitor C may include an electrode E1 and an electrode E2 facing each other. In some embodiments, the insulation layer 128 is a multi-layer structure. The electrode E1 and the electrode E2 may be located in different layers of this multi-layer structure. In other embodiments, the electrode E1 may also be located in the dielectric layer 126, and the electrode E2 may be located in the insulation layer 128. Additionally, orthographic projections of the electrode E1 and the electrode E2 on the first carrier 122 may overlap with each other. In some embodiments, taking the pixel circuit substrate 120b and the pixel circuit substrate 120c for example, each of the pixel circuits 130 may further include a wiring L. The wiring L may be located in the dielectric layer 126 or in the insulation layer 128. In some embodiments, the transistor T, the capacitor C and the wiring L in each of the pixel circuits 130 may be electrically connected with one another. In some embodiments, each of the electrode E1, the electrode E2 and the wiring L may be made of a metal material, any other conductive material or a stack layer consisting of the metal material and the afore-mentioned any other conductive material. The metal material may include aluminum, copper, molybdenum, titanium and so on, and the afore-mentioned any other conductive material may include a metal alloy, metal nitride, metal oxide, metal oxynitride, or another suitable material.

A method of forming each of the pixel circuit substrates may include forming a plurality of vertical connection structures 132 in the insulation layer 128. In some embodiments, the vertical signal connection structures 132 may include a vertical connection structure 132a, a vertical connection structure 132b and a vertical connection structure 132c. The vertical connection structure 132a may extend downwards from a top surface of the insulation layer 128 to be electrically connected with the pixel circuit 130 (for example, the transistor T of the pixel circuit 130). In some embodiments, the vertical connection structure 132a may be electrically connected with the drain electrode D of the transistor T. In some embodiments, taking the vertical connection structure 132a in the pixel circuit substrate 120a for example, the vertical connection structure 132a may include a conductive via 134a. In these embodiments, the conductive via 134a may extend from the transistor T (for example, the drain electrode D of the transistor T) to the top surface of the insulation layer 128. In some other embodiments, taking the pixel circuit substrate 120b and the pixel circuit substrate 120c for example, the vertical connection structure 132a may further include a pad 136a. In some embodiments, a top surface of the pad 136a may be substantially coplanar with the top surface of the insulation layer 128. The conductive via 134a may be electrically connected between the transistor T (for example, the drain electrode D of the transistor T) and the pad 136a. In other embodiments, the pad 136a may be formed on the top surface of the insulation layer 128. In other words, the conductive via 134a may extend to the top surface of the insulation layer 128 and be electrically connected with the pad 136a on the insulation layer 128. In an alternative embodiment, the vertical connection structure 132a may also be electrically connected with the source electrode S of the transistor T. In these embodiments, the conductive via 134a may also be electrically connected with the source electrode S of the transistor T.

The vertical connection structure 132b may extend from the substrate 124 into the dielectric layer 126 and the insulation layer 128, and be electrically connected with the pixel circuit 130. In some embodiments, the vertical connection structure 132b may be electrically connected with the transistor T (for example, the gate electrode G of the transistor T) or the capacitor C (for example, the electrode E1 or the electrode E2 of the capacitor C). In some embodiments, the vertical connection structure 132b may include a pad 136b and a conductive via 134b. The pad 136b is fainted on the carrier 122, and the substrate 124 covers the pad 136b. The conductive via 134b extends upwards from a top surface of the pad 136b to penetrate the substrate 124, and extends into the dielectric layer 126 and the insulation layer 128, so as to be electrically connected with the transistor T (for example, the gate electrode G of the transistor T) or the capacitor C (for example, the electrode E1 or the electrode E2 of the capacitor C) of the pixel circuit 130.

The vertical connection structure 132c penetrates the substrate 124, the dielectric layer 126 and the insulation layer 128. In some embodiments, taking the vertical connection structure 132c of the pixel circuit substrate 120a for example, the vertical connection structure 132c may include a pad 136c and a conductive via 134c. The pad 136c is formed on the carrier 122, and the substrate 124 covers the pad 136c. The conductive via 134c extends upwards from a top surface of the pad 136c to penetrate the substrate 124, the dielectric layer 126 and the insulation layer 128. In some other embodiments, taking the vertical connection structures 132c of the pixel circuit substrate 120b and the pixel circuit substrate 120c for example, each of the vertical connection structures 132c includes a pair of pads 136c and the conductive via 134c. The pair of pads 136c may include a lower pad and an upper pad. The lower pad of the pair of pads 136c may be formed on the carrier 122 and covered by the substrate 124. The upper pad of the pair of pads 136c may be formed in a top portion of the insulation layer 128, and the top surface of the insulation layer 128 may expose a top surface of the upper pad. In these embodiments, the conductive via 134c is electrically connected between the pair of pads 136c. In some embodiments, the conductive via 134c, the conductive via 134b and the conductive via 134c may be respectively made of copper, aluminum, molybdenum, titanium, silver or a combination thereof. The pad 136a, the pad 136b and the pad 136c may be made of copper, aluminum, molybdenum, titanium, silver, a transition metal compound or a combination thereof.

In some embodiments, the step (i.e., step S100) of forming the signal line substrate 100 may be performed before or after the step (i.e., step S102) of forming the pixel circuit substrates. In other embodiments, steps S100 and S102 may also be performed simultaneously. The sequence of steps S100 and S102 is not limited in the invention.

Referring to FIG. 2C, step S104 is performed, where a light emitting device layer 140 is formed on one of the pixel circuit substrates. For example, the light emitting device layer 140 may be formed on the pixel circuit substrate 120a. In some embodiments, a protection layer 142 and a spacing structure 144 may be first formed on the pixel circuit substrate 120a before the light emitting device layer 140 is formed. In some embodiments, the protection layer 142 may include an inorganic layer 142a and an organic layer 142b which are sequentially stacked on the pixel circuit substrate 120a. For example, the inorganic layer may be made of silicon oxide, silicon nitride or silicon oxynitride. The organic layer may be made of a photosensitive resin, such as a phenol resin, an epoxy resin, an acrylic resin or a combination thereof. The spacing structure 144 is formed on the protection layer 142 and has a plurality of openings P exposing the protection layer 142. In some embodiments, the spacing structure 144 may be made of a photosensitive resin, such as a phenol resin, an epoxy resin, an acrylic resin or a combination thereof.

The light emitting device layer 140 includes a plurality of light emitting devices. For example, the light emitting devices may include a light emitting device 140a, a light emitting device 140b and a light emitting device 140c. In some embodiments, each of the light emitting devices may be an organic light emitting diode or an inorganic light emitting diode. The light emitting device 140a, the light emitting device 140b and the light emitting device 140c may be respectively formed in the openings P of the spacing structure 144. In some embodiments, dominant wavelength ranges of the light emitting device 140a, the light emitting device 140b and the light emitting device 140c may be different from one another, namely, the light emitting device 140a, the light emitting device 140b and the light emitting device 140c may emit light in different colors. In some embodiments, taking the light emitting device 140a for example, each light emitting device may include an anode AN, an emission layer EM and a cathode CA. The anode AN, the emission layer EM and the cathode CA may be sequentially formed in each of the openings P. In some embodiments, the cathode CA may fully cover one of the pixel circuit substrates (for example, the pixel circuit substrate 120a). In other words, the cathode CA may extend outwards from the opening P to a top surface of the spacing structure 144. In some embodiments, the anode AN may extend from a bottom surface of the opening P to penetrate the protection layer 142 to be electrically connected with at least one of the vertical connection structures 132. For example, the anode AN of the light emitting device 140a may penetrate the protection layer 142 to be electrically connected with the vertical connection structure 132a of the pixel circuit substrate 120a. In some embodiments, the anode AN and the vertical connection structure (for example, the vertical connection structure 132a) electrically connected with the anode AN may be formed in the same process step together. In other words, the anode AN may penetrate the protection layer 142 and extend into the insulation layer 128 of the pixel circuit substrate (for example, the pixel circuit substrate 120a), so as to be electrically connected with the transistor T of the pixel circuit 130. In some embodiments, the anode AN may be electrically connected with the drain electrode D of the transistor T. In other embodiments, the anode AN may also be electrically connected with the source electrode S of the transistor T. In this way, a part of the anode AN which is located in the insulation layer 128 may be employed as the vertical connection structure (for example, the vertical connection structure 132a). In some embodiments, the anode AN may be made of indium tin oxide (ITO), silver, aluminum, titanium, molybdenum, copper or a combination thereof. The emission layer EM may be made of an organic luminous material or an inorganic luminous material. The cathode CA may be made of magnesium, silver, gold, calcium, lithium, chromium, aluminum, lithium fluoride or a combination thereof.

In some embodiments, the light emitting device layer 140 may further include a package layer 146. The package layer 146 covers a plurality of light emitting devices (for example, including the light emitting device 140a, the light emitting device 140b and the light emitting device 140c). The package layer 146 may be made of silicon nitride, aluminum oxide, silicon carbonitride, silicon oxynitride, an acrylic resin, hexamethyl disiloxane (HMDSO) or glass.

Referring to FIG. 2D to FIG. 2H, step S106 is performed, where the pixel circuit substrates (for example, including the pixel circuit substrate 120a, the pixel circuit substrate 120b and the pixel circuit substrate 120c) are combined and stacked with one another on the signal line substrate 100. In some embodiments, a method of combining and stacking the pixel circuit substrates with one another on the signal line substrate 100 may include the following sub steps.

Referring to FIG. 2D, a second carrier 150 is bonded onto the light emitting device layer 140 of one of the pixel circuit substrates (for example, the pixel circuit substrate 120a). In some embodiments, the second carrier 150 may be a glass carrier. In this way, the first carrier 122 and the second carrier 150 are located on two opposite sides of the pixel circuit substrate (for example, the pixel circuit substrate 120a). In other words, the first carrier 122 is adjacent to the pixel circuit 130, and the second carrier 150 is adjacent to the light emitting device layer 140. Then, the first carrier 122 is removed to expose a bottom surface of the substrate 124 and bottom surfaces of the vertical connection structures (for example, the vertical connection structure 132b and the vertical connection structure 132c).

Referring to FIG. 2E, the structure (for example, including the pixel circuit substrate 120a, the light emitting device layer 140 and the second carrier 150) illustrated in FIG. 2D is bonded onto the insulation layer 128 of another pixel circuit substrate (for example, the pixel circuit substrate 120b). For example, the vertical connection structure 132b of the pixel circuit substrate 120a may be electrically connected with the vertical connection structure 132b or the vertical connection structure 132c of the pixel circuit substrate 120b. In other words, the pad 136b of the pixel circuit substrate 120a is substantially aligned to an upper pad of the pair of pads 136b or an upper pad of the pair of pads 136c of the pixel circuit substrate 120h. On the other hand, the vertical connection structure 132c of the pixel circuit substrate 120a may be electrically connected with the vertical connection structure 132a or the vertical connection structure 132c of the pixel circuit substrate 120b. In other words, the pad 136c of the pixel circuit substrate 120a is substantially aligned to the pad 136a or the upper pad of the pair of pads 136c of the pixel circuit substrate 120b. Thereafter, the first carrier 122 connected with the lower pixel circuit substrate (for example, the pixel circuit substrate 120b) is removed to expose the bottom surface of the substrate 124 and the bottom surfaces of the vertical connection structures (for example, the vertical connection structure 132h and the vertical connection structure 132c).

Referring to FIG. 2F, the structure (for example, including the pixel circuit substrate 120a, the pixel circuit substrate 120b, the light emitting device layer 140 and the second carrier 150) illustrated in FIG. 2E is bonded onto the insulation layer 128 of another pixel circuit substrate (for example, the pixel circuit substrate 120c). For example, the vertical connection structure 132b of the pixel circuit substrate 120b may be electrically connected with the vertical connection structure 132b or the vertical connection structure 132c of the pixel circuit substrate 120c. In other words, the lower pad of the pair of pads 136b of the pixel circuit substrate 120b is substantially aligned to the upper pad of the pair of pads 136b or the upper pad of the pair of pads 136c of the pixel circuit substrate 120c. On the other hand, the vertical connection structure 132c of the pixel circuit substrate 120b may be electrically connected with the vertical connection structure 132a or the vertical connection structure 132c of the pixel circuit substrate 120c. In other words, the lower pad of the pair of pads 136c of the pixel circuit substrate 120b is substantially aligned to the pad 136a or the upper pad of the pair of pads 136c of the pixel circuit substrate 120c. Thereafter, the first carrier 122 connected to the lower pixel circuit substrate (for example, the pixel circuit substrate 120c) is removed to expose the bottom surface of the substrate 124 and the bottom surfaces of the vertical connection structures (for example, the vertical connection structure 132b and the vertical connection structure 132c).

Referring to FIG. 2D to FIG. 2H, the structure (for example, including the pixel circuit substrate 120a, the pixel circuit substrate 120b, the pixel circuit substrate 120c, the light emitting device layer 140 and the second carrier 150) illustrated in FIG. 2F is bonded onto the insulation layer 108 of the signal line substrate 100. For example, the vertical connection structure 132b and the vertical connection structure 132c of the pixel circuit substrate 120c may be electrically connected with the vertical connection structures 110 of the signal line substrate 100. In other words, each of the pads 114 of the signal line substrate 100 may be substantially aligned to the lower pad of the pair of pads 136b or the lower pad of the pair of pads 136c of the pixel circuit substrate 120c. Then, the first carrier 102 connected to the lower signal line substrate 100 is removed to expose the bottom surface of the substrate 104.

In some embodiments, step S104 may be performed after step S106. In other words, in these embodiments, a plurality of pixel circuit substrates (for example, the pixel circuit substrate 120a, the pixel circuit substrate 120b and the pixel circuit substrate 120c) may be first bonded and stacked with one another on the signal line substrate 100, and then, the light emitting device layer 140 is formed on the upmost one of the pixel circuit substrates. Those will ordinary skills in the art may change the sequence of steps S104 and S106 based on a process requirement, and the invention is not limited thereto.

Thereafter, step S108 may be selectively performed to bond the structure illustrated in FIG. 2H onto a transparent substrate (not shown). In some embodiments, the transparent substrate may be bonded to a side of the signal line substrate 100 opposite to the multiple pixel circuit substrates (for example, including the pixel circuit substrate 120a to the pixel circuit substrate 120c). The transparent substrate may be, for example, an array substrate. In some other embodiments, step S108 may not be performed. In these embodiments, the method of forming the signal line substrate 100 in step S100 may include forming the insulation layer 108, the signal lines 106 and the vertical signal connection structures 110 on a transparent substrate (not shown). The insulation layer 108 covers the signal lines 106. The vertical signal connection structures 110 are formed in the insulation layer 108 and electrically connected with the signal lines 106 respectively.

As such, the manufacture process of the display apparatus 10 of some embodiments of the invention has been completed. Thereafter, the structure of the display apparatus 10 of the embodiments of the invention will be further described with reference to FIG. 2H.

Referring to FIG. 2H, in the display apparatus 10, a plurality of light emitting devices 140 (for example, including the light emitting device 140a, the light emitting device 140b and the light emitting device 140c) are respectively electrically connected with the pixel circuits 130 via a first set of the vertical connection structures 132 of the pixel circuit substrates (for example, the pixel circuit substrate 120a, the pixel circuit substrate 120b and the pixel circuit substrate 120c). For example, corresponding to the light emitting device 140a, the first set of the vertical signal connection structures 132 may include the vertical connection structure 132a of the pixel circuit substrate 120a. Corresponding to the light emitting device 140b, the first set of the vertical signal connection structures 132 may include the vertical connection structure 132c of the pixel circuit substrate 120a and the vertical connection structure 132a of the pixel circuit substrate 120b which are electrically connected with each other. Corresponding to the light emitting device 140c, the first set of the vertical signal connection structures 132 may include the vertical connection structures 132c of the pixel circuit substrate 120a and the pixel circuit substrate 120b and the vertical connection structure 132a of the pixel circuit substrate 120c which are electrically connected with each other.

By describing the display apparatus 10 in another manner, the first set of the vertical connection structures 132 may also be referred to as a plurality of first vertical connection structures VC1. The first vertical connection structures VC1 are disposed in the pixel circuit substrates (for example, the pixel circuit substrate 120a, the pixel circuit substrate 120b and the pixel circuit substrate 120c). The first vertical connection structures VC1 are respectively electrically connected between the light emitting devices 140 (for example, the light emitting device 140a, the light emitting device 140b and the light emitting device 140c) and the pixel circuits 130. In some embodiments, at least one of the first vertical connection structures VC1 penetrates at least one of the pixel circuit substrates (for example, the pixel circuit substrates 120a to 120c). For example, the first vertical connection structure VC1 electrically connected with the light emitting device 140b penetrates the pixel circuit substrate 120a. Additionally, the first vertical connection structure VC1 electrically connected with the light emitting device 140c penetrates the pixel circuit substrate 120a and the pixel circuit substrate 120b. The first vertical connection structures VC1 may be respectively connected with the corresponding light emitting devices 140 and pixel circuits 130, such that the pixel circuits 130 may drive the corresponding light emitting devices 140 through the first vertical connection structures VC1.

On the other hand, in the display apparatus 10, a plurality of vertical signal connection structures 110 (for example, the vertical signal connection structures 110a to 110d) are electrically connected with the pixel circuits 130 via a second set of the vertical connection structures 132 of the pixel circuit substrates (for example, the pixel circuit substrates 120a to 120c) respectively. For example, corresponding to the vertical signal connection structure 110a, the second set of the vertical signal connection structures 132 may include the vertical connection structures 132c of the pixel circuit substrate 120c and the pixel circuit substrate 120b and the vertical connection structure 132b of the pixel circuit substrate 120a which are electrically connected with each other. Corresponding to the vertical signal connection structure 110b, the second set of the vertical signal connection structures 132 may include the vertical connection structure 132c of the pixel circuit substrate 120c and the vertical connection structure 132b of the pixel circuit substrate 120b which are electrically connected with each other. Corresponding to the vertical signal connection structure 110c, the second set of the vertical signal connection structures 132 may include the vertical connection structure 132b of the pixel circuit substrate 120c. Corresponding to the vertical signal connection structure 110d, the second set of the vertical signal connection structures 132 may include the vertical connection structure 132b of the pixel circuit substrates 120a to 120c which are electrically connected with one another.

By describing the display apparatus 10 in another manner, the second set of the vertical connection structures 132 may also be referred to as a plurality of second vertical connection structures VC2. The second vertical connection structures VC2 are disposed in the pixel circuit substrates (for example, the pixel circuit substrate 120a to 120c). The second vertical connection structures VC2 are electrically connected between the pixel circuits 130 and the vertical signal connection structures 110 respectively. In some embodiments, at least one of the second vertical connection structures VC2 penetrates at least one of the pixel circuit substrates (for example, the pixel circuit substrates 120a to 120c). For example, the second vertical connection structure VC2 electrically connected with the vertical signal connection structures 110a and 110d penetrates the pixel circuit substrates 120a and 120b. Additionally, the second vertical connection structure VC2 electrically connected with the vertical signal connection structure 110b penetrates the pixel circuit substrate 120a. For example, the second vertical connection structures VC2 may be respectively coupled to the signals lines 106 employed as scan lines, data lines, working electrodes and reference electrodes, thereby implementing various signal transmissions.

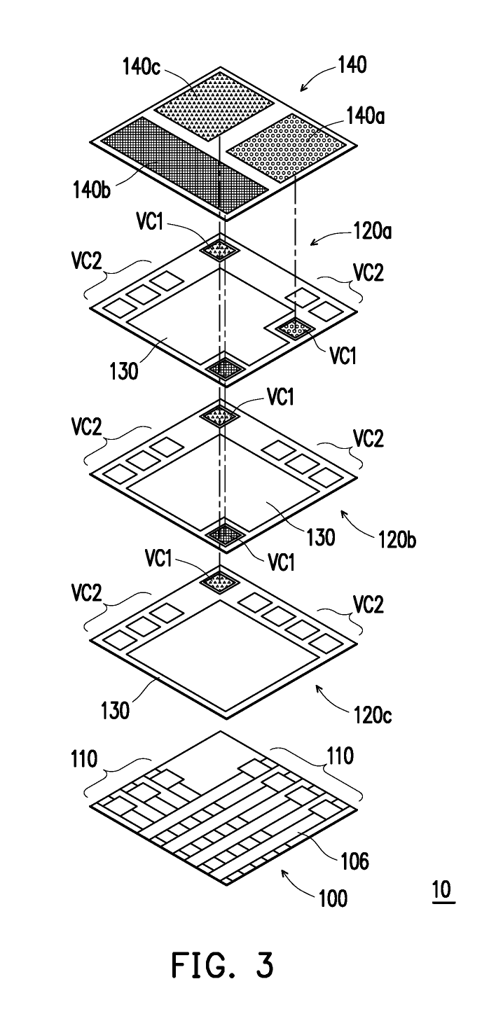

FIG. 3 is a schematic three-dimensional (3D) exploded diagram illustrating the display apparatus 10 according to some embodiments of the invention. Thereafter, a 3D structure of the display apparatus 10 will be further described.

Referring to FIG. 3, the display apparatus 10 may include pixels each of which includes a plurality of sub-pixels. In the display apparatus 10, the first vertical connection structures VC1 are electrically connected between the light emitting devices (for example, the light emitting devices 140a to 140c) and the pixel circuits 130 respectively. The second vertical connection structures VC2 are electrically connected between the pixel circuits 130 and the vertical signal connection structures 110. In some embodiments, a plurality of orthographic projections of the pixel circuits 130 on the signal line substrate 100 overlap with one another. Additionally, in some embodiments, a plurality of orthographic projections of the light emitting devices (for example, the light emitting devices 140a to 140c) and of the pixel circuits 130 on the signal line substrate 100 overlap with one another.

Based on the above, in the embodiments of the invention, by stacking the pixel circuit substrates (for example, the pixel circuit substrate 120a to 120c) on the signal line substrate 100, the pixel circuits 130 may be disposed on different horizontal planes within a single pixel region. In comparison with the pixel circuits which are formed on the same horizontal plane within a single pixel region, a layout area of each pixel circuit 130 may be less restricted in the embodiments of the invention. In this way, a process margin may be increased. Additionally, an area of the pixel region may also be reduced, thereby increasing a resolution of the display apparatus. On the other hand, in comparison with cases where some of the signal lines are disposed in the periphery (the border region) of the pixel region, all the signal lines 106 may be disposed under the pixel circuits 130 in the embodiments of the invention. In other words, all the signal lines 106 may be formed within the range of the pixel region in the embodiments of the invention. In this way, the display apparatus 10 of the embodiments of the invention can achieve the object of a narrow-border or borderless design.

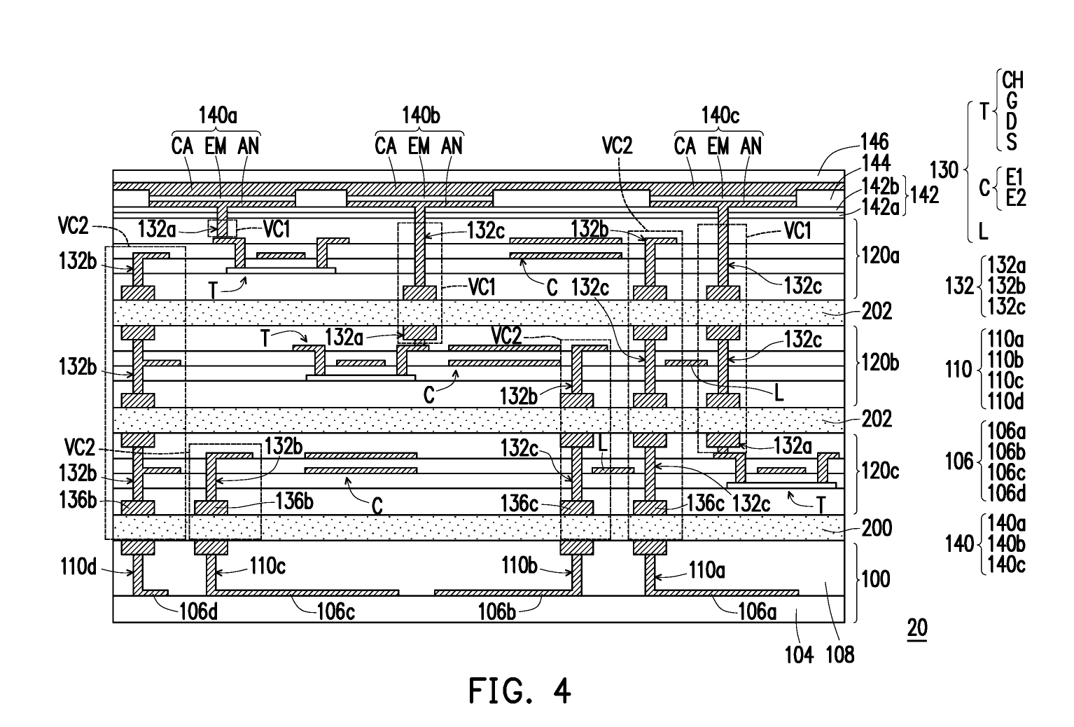

FIG. 4 is a schematic cross-sectional view illustrating a display apparatus 20 according to some embodiments of the invention.

Referring to FIG. 2H and FIG. 4, the display apparatus 20 illustrated in FIG. 4 is similar to the display apparatus 10 illustrated in FIG. 2H. The difference between the two lies in the display apparatus 20 further including a first anisotropic conductive layer 200 and a plurality of second anisotropic conductive layers 202. The first anisotropic conductive layer 200 is disposed between the signal line substrate 100 and the pixel circuit substrates (for example, the pixel circuit substrate 120b to 120c). For example, the first anisotropic conductive layer 200 may be located between the signal line substrate 100 and the pixel circuit substrate 120c. Each of the second anisotropic conductive layers 200 may be disposed between two of the pixel circuit substrates which are the most adjacent. For example, the second anisotropic conductive layers 202 may be respectively disposed between the pixel circuit substrates 120c and 120b, and between the pixel circuit substrate 120b and 120a.

A manufacturing method of the display apparatus 20 is similar to that of the display apparatus 10 illustrated in FIG. 2A to FIG. 2H. Only the difference between the two will be described below, and the same or similar parts will no longer repeated. Before the step of combining and stacking the pixel circuit substrates with one another on the signal line substrate 100 (step S104), the manufacturing method of the display apparatus 20 further includes forming a first anisotropic conductive layer 200 on the signal line substrate 100 and forming a second anisotropic conductive layer 202 on at least one of the pixel circuit substrates. For example, the second anisotropic conductive layer 202 may be formed on each of the pixel circuit substrates 120c and 120b.

Based on the above, in the embodiments of the invention, by stacking the pixel circuit substrates on the signal line substrate, the pixel circuits can be disposed on different horizontal planes within the same pixel region. In comparison with the pixel circuits which are formed on the same horizontal plane within the same pixel region, the manufacturing method of the display apparatus according to the embodiments of the invention can have more preferable process margin. Additionally, the area of the pixel region can also be reduced, thereby increasing the resolution of the display apparatus. On the other hand, in comparison with cases where some of the signal lines are disposed in the periphery (the border region) of the pixel region, all the signal lines can be disposed under the pixel circuits in the embodiments of the invention. In other words, all the signal lines of the embodiments of the invention can be formed within the range of the pixel region. In this way, the display apparatus of the embodiments of the invention can narrow border region of the display apparatus.

Although the invention has been disclosed by the above embodiments, they are not intended to limit the invention. It will be apparent to one of ordinary skill in the art that modifications and variations to the invention may be made without departing from the spirit and scope of the invention. Therefore, the scope of the invention will be defined by the appended claims.

What is claimed is:

1. A display apparatus, comprising:
a signal line substrate, comprising a plurality of signal lines and a plurality of vertical signal connection structures electrically connected with the signal lines respectively;
a plurality of pixel circuit substrates, stacked on the signal line substrate, wherein each of the pixel circuit substrates comprises a pixel circuit; and
a light emitting device layer, disposed on the pixel circuit substrates and comprising a plurality of light emitting devices;
a plurality of first vertical connection structures, disposed in the pixel circuit substrates and electrically connected between the light emitting devices and the pixel circuits respectively; and
a plurality of second vertical connection structures, disposed in the pixel circuit substrates and electrically connected between the pixel circuits and the vertical signal connection structures respectively.

2. The display apparatus according to claim 1, wherein each of the pixel circuits comprises at least one transistor.

3. The display apparatus according to claim 1, wherein at least one of the first vertical connection structures penetrates at least one of the pixel circuit substrates.

4. The display apparatus according to claim 1, wherein at least one of the second vertical connection structures penetrates at least one of the pixel circuit substrates.

5. The display apparatus according to claim 1, wherein a plurality of orthographic projections of the pixel circuits on the signal line substrate overlap with one another.

6. The display apparatus according to claim 1, wherein a plurality of orthographic projections of the light emitting devices and of the pixel circuits on the signal line substrate overlap with one another.

7. The display apparatus according to claim 1, further comprising a first anisotropic conductive layer and a plurality of second anisotropic conductive layers, wherein the first anisotropic conductive layer is disposed between the signal line substrate and the pixel circuit substrates, and each of the second anisotropic conductive layers is disposed between two of the pixel circuit substrates.

8. A manufacturing method of a display apparatus, comprising:
forming a signal line substrate, wherein the signal line substrate comprises a plurality of signal lines and a plurality of vertical signal connection structures electrically connected with the signal lines respectively;
forming a plurality of pixel circuit substrates, wherein each of the pixel circuit substrates comprises a pixel circuit and a plurality of vertical connection structures;
forming a light emitting device layer on one of the pixel circuit substrates, wherein the light emitting device layer comprises a plurality of light emitting devices; and
bonding and stacking the pixel circuit substrates with one another on the signal line substrate, wherein the light emitting device layer covers the pixel circuits, and the light emitting devices are respectively electrically connected with the pixel circuits via a first set of the vertical connection structures and are respectively electrically connected with the pixel circuits via a second set of the vertical connection structures.

9. The manufacturing method of the display apparatus according to claim 7, before the step of bonding and stacking the pixel circuit substrates with one another on the signal line substrate, the manufacturing method of the display apparatus further comprises:
forming a first anisotropic conductive layer on the signal line substrate; and
forming a second anisotropic conductive layer on at least one of the pixel circuit substrates.

10. The manufacturing method of the display apparatus according to claim 7, wherein the signal line substrate comprises a transparent substrate and an insulation layer, the insulation layer is formed on the transparent substrate, and the signal lines and the vertical signal connection structures are formed in the insulation layer.

11. The manufacturing method of the display apparatus according to claim 7, wherein after the step of bonding and stacking the pixel circuit substrates with one another on the signal line substrate, the manufacturing method of the display apparatus further comprises:
bonding the signal line substrate onto a transparent substrate.
